(19) United States
(12) Patent Application Publication
(10) Pub. No.: US 2019/0385949 A1
(43) Pub. Date: Dec. 19, 2019

(54) AMORPHOUS OXIDE SEMICONDUCTOR MEMORY DEVICES

(71) Applicant: INTEL CORPORATION, Santa Clara, CA (US)

(72) Inventors: Van H. Le, Portland, OR (US); Abhishek A. Sharma, Hillsboro, OR (US); Gilbert Dewey, Beaverton, OR (US); Ravi Pillarisetty, Portland, OR (US); Shriram Shivaraman, Hillsboro, OR (US); Yih Wang, Portland, OR (US); Jack T. Kavalieros, Portland, OR (US); Tahir Ghani, Portland, OR (US)

(73) Assignee: INTEL CORPORATION, Santa Clara, CA (US)

(21) Appl. No.: 16/464,024

(22) PCT Filed: Dec. 27, 2016
(86) PCT No.: PCT/US2016/068659

§ 371 Date: May 24, 2019

(51) Int. Cl. H01L 23/528; H01L 27/108; G11C 5/06

(52) U.S. Cl. CPC H01L 23/5283; H01L 27/10808; G11C 5/063; H01L 27/10855; H01L 27/10873; H01L 27/10897

(57) ABSTRACT

Integrated circuit structures are described that include back end memory devices that are integrated into one or more back end interconnect layers of an integrated circuit. Examples of the back end memory devices described include one transistor and one capacitor (“1T/1C”) memory cell devices that use an oxide semiconductor layer (e.g., indium gallium zinc oxide) as an element of the transistor portion (1T) of the back end memory cell. This produces a memory device with a low off state leakage current, improving memory device performance while also reducing memory device size.

### BACKGROUND

Embedded dynamic random access memory (eDRAM) is a type of memory device that is integrated onto a same package substrate (or “die”) as a microprocessor chip (such as a central processing unit or “CPU”), thus forming a “multichip module.” Integration of both a memory devices and a CPU proximate to one another on a same package substrate enables direct communication between the memory device and the CPU through a bus at very high bandwidths and low signal latencies.

Generally, a transistor of a 1 transistor/1 capacitor (“1T/1C”) eDRAM device is fabricated in the front-end (or front-end-of-line (FEOL)) on and/or within a semiconducting substrate while a corresponding capacitor is placed in the back-end (or back-end-of-line (BEOL)). A transistor and corresponding capacitor are then placed in electrical communication with one another by metal interconnect layers formed in the BEOL. The BEOL is the portion of IC fabrication where individual semiconductor devices (whether embedded memory or logic transistors) are interconnected to one another with electrically conductive features such as metal lines and metal vias. These interconnects are encapsulated in a dielectric material. The BEOL may include any number of layers, depending on the target application or end use.

### BRIEF DESCRIPTION OF THE DRAWINGS

FIG. 1A is a schematic cross-section taken along a direction parallel to a gate of a transistor of an example eDRAM device, which is disposed within a device layer fabricated within the FEOL.

FIG. 1B is a schematic cross-section taken along a direction parallel to a gate of a transistor of an example back end memory device disposed within an interconnect layer and fabricated within the BEOL, in accordance with an embodiment of the present disclosure.

FIG. 2 is a flow diagram of an example method for fabricating a back end memory device within an interconnect layer, in accordance with an embodiment of the present disclosure.

FIGS. 3A-3G are cross-sectional views of a series of back end memory device structures taken along a direction parallel to a gate of the back end memory device, the views illustrating formation of a back end memory device according to the method shown in FIG. 2, in accordance with an embodiment of the present disclosure.

FIG. 4 is a cross-section side view of a back end memory device cross-section taken along a direction parallel to a gate of the back end memory device, in accordance with an embodiment of the present disclosure.

FIG. 5 is a cross-section side view of an alternative bottom gate configuration of a back end memory device taken along a direction parallel to a gate of the back end memory device, in accordance with an embodiment of the present disclosure.

FIG. 6 is a depiction of a mobile computing system configured in accordance with an embodiment of the present disclosure.

The figures depict various embodiments of the present disclosure for purposes of illustration only. Numerous variations, configurations, and other embodiments will be apparent from the following detailed discussion.

### DETAILED DESCRIPTION

Techniques are disclosed for forming integrated circuit structures that include back end memory devices (alternatively referred to as back end memory “cells”) integrated into one or more interconnect layers. This is in contrast to standard eDRAM memory devices that include elements that are fabricated within both a device layer and a back end layer. Examples of the back end memory devices variously described herein include, for instance, one transistor and one capacitor (“1T/1C”) memory devices that use a BEOL-compatible oxide semiconductor layer as an element of the transistor. Other memory cell configurations can be used as well, as will be appreciated. Examples of oxide semiconductors that can be used in any such back end memory devices include, for instance, Indium Gallium Zinc Oxide (“IGZO”), In₂O₃, SnO, Ga₂O₃, ZnO, Zinc Oxide Nitride (“ZON”), and Indium Zinc Oxide (“IZO”).

The disclosed techniques may provide various advantages over traditionally fabricated and configured embedded memory devices (e.g., eDRAM or SRAM) disposed within a device layer of an integrated circuit and/or fabricated from traditional capacitor materials. For example, back end memory devices described herein include a naturally low leakage current when the transistor of the back end memory device is turned off. This low “off-state” leakage improves the storage duration of a memory device and thus reduces the energy consumption of a device as a whole because the back end memory devices require less frequent capacitor re-charges to maintain the charge state. Also, the naturally low leakage current of the wide bandgap oxide semiconductor materials enables the dimensions of the back end memory devices to be further reduced compared to standard memory devices. Also, unlike standard memory devices, the reduced dimensions of the back end memory devices of the present disclosure is not accompanied by an increase in leakage current as is commonly observed in standard embedded memory devices. This advantage is due, at least in part, to the use of the oxide semiconductor as an element of the back end memory device transistor.

Because of an inverse relationship exhibited between standard embedded memory device size and leakage current (as device size decreases, leakage current increases), it has been challenging in practice for embedded memory device dimensions to shrink at the same rate as logic transistors in successive technology generations to increase memory density. As a result, scaling eDRAM technology to increase performance and device density while maintaining cost has become challenging.

In light of this, the disclosed techniques provide various advantages beyond performance of an embedded memory device itself. For example, the disclosed techniques facilitate an increase in eDRAM cell density on a substrate while decreasing power consumption. Also, as already described above, the techniques described herein enable a reduction in memory device dimensions without a corresponding increase in leakage, thus enabling smaller memory devices relative to standard memory devices. The disclosed techniques can, in some examples, increase an amount of area available on a substrate for peripheral memory circuitry (e.g., sense amplifier; row and column decoders) by disposing the peripheral memory circuitry on a semiconductor substrate below a corresponding back end memory cell. This is because the back end memory devices (including both the 1T and 1C of a memory cell) of the present disclosure are disposed in an interconnect layer and not in a device layer, unlike standard embedded memory devices. Also, the disclosed techniques facilitate an increase in transistor density because back end memory devices described herein can be configured as a stack of layers. This is in contrast to standard memory devices that are often configured so that transistors are disposed in a device layer on a substrate and adjacent the peripheral memory circuitry that is also disposed in the device layer on the substrate. Thus, the area occupied by each back end memory devices is reduced compared to a standard eDRAM device. In some examples, these advantages can increase eDRAM density by as much as a factor of 1.5 or more. Numerous configurations and variations will be apparent in light of this disclosure.

General Overview

As indicated above, eDRAM devices and other embedded memories (generally referred to herein as “embedded memory” or “embedded memory devices”) are often used to store bits of data proximate to, and on or within a same packaging substrate as, a logic chip (including, but not limited to, a CPU). In this way, embedded memory increases the speed with which logic transistors of the logic chip can operate by reducing delays caused by transmitting signals between separate package substrates.

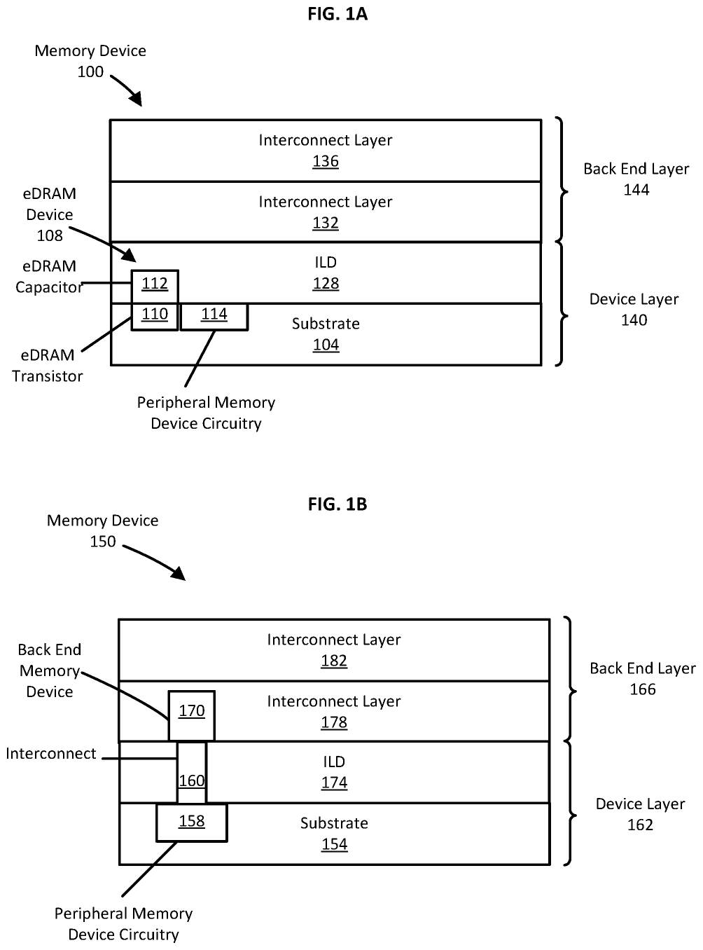

A schematic illustration of a standard embedded memory device 100, in this case an eDRAM device, is shown in FIG. 1A. This example is composed of a substrate 104, an eDRAM device 108, inter layer dielectric (ILD) 128, and interconnect layers 132 and 136. It will be appreciated that the depiction in FIG. 1A is simplified, omitting various features and details, for clarity of explanation.

As shown, the memory device 100 can be broadly characterized as including a device layer 140 and a back end layer 144. Within the device layer 140 is shown, in this example, a transistor 110 of the eDRAM device 108 and peripheral memory circuitry 114. The peripheral memory circuity includes various circuits, including, but not limited to sense amplifier; row and column decoders, which are often disposed on the substrate 104 proximate to a corresponding eDRAM transistor 114. The eDRAM device 108 also includes a capacitor 112 in electrical communication with the transistor 110. The capacitor 112 can store a charge to indicate a binary value of “1” and can be discharged (or not store a charge) to indicate a binary value of “0.” The transistor 110 associated with the eDRAM capacitor 112 controls the charge state of the eDRAM capacitor 112 and also controls the “reading” (i.e., the determination of the charge state) of the capacitor when so instructed by another component of an integrated circuit. It will be appreciated that other types of memory devices (e.g., SRAM) may be disposed within the device layer 140 instead of or in addition to the eDRAM device 108 that is shown. It will be appreciated that multiple eDRAM devices (similar to the eDRAM device 108) can be disposed within the memory device 100 and that only a single eDRAM device is depicted in FIG. 1A for clarity of explanation.

On the device layer 140 is the back end layer 144. The back end layer 144 illustrated includes two interconnect layers 132 and 136. The interconnect layers 132, 136 that compose the back end layer 144 typically include metal features (not shown) such as vias and lines that connect individual devices (whether logic transistors or embedded memory devices). These metal features are generally separated from one another by interlayer dielectric to prevent short circuiting and to facilitate various fabrication processes (e.g., patterning via planarization and photolithography). Generally, more and more individual devices are placed in electrical communication with one another the further an interconnect layer is from the device layer, although this is not necessarily the case.

FIG. 1B is a schematic illustration of a memory device 150 that includes a back end memory device of the present disclosure. Analogous to the memory device 100 shown in FIG. 1A, the memory device 150 includes a substrate 154 a device layer 162, and a back end layer 166. However, unlike the memory device 100, the memory device 150 includes a back end memory device 170 disposed in an interconnect layer 178 of the back end layer 166. Disposing the back end memory device 170 within the interconnect layer 178, rather than within the device layer 162 increases the density of corresponding transistors formed within the device layer 162.

That is, by placing the embedded memory of the memory device 150 within the interconnect layer 178, a number of transistors within the device layer 162 increases because surface area that would otherwise be occupied by the various elements of the eDRAM device 108 can instead be used for a transistor. Also, as shown, density of memory devices 150 can increase compared to standard memory device 108 because peripheral memory device circuitry 158 can be disposed underneath (and in some cases, directly underneath) the memory device 170. This is in contrast to the memory device 100 in which peripheral memory device circuitry 114 is disposed on the substrate proximate to other elements (e.g., one or more of the transistor 110 and the capacitor 112). As shown, the back end memory device 170 is connected to the peripheral memory device circuitry 158 via interconnect 160.

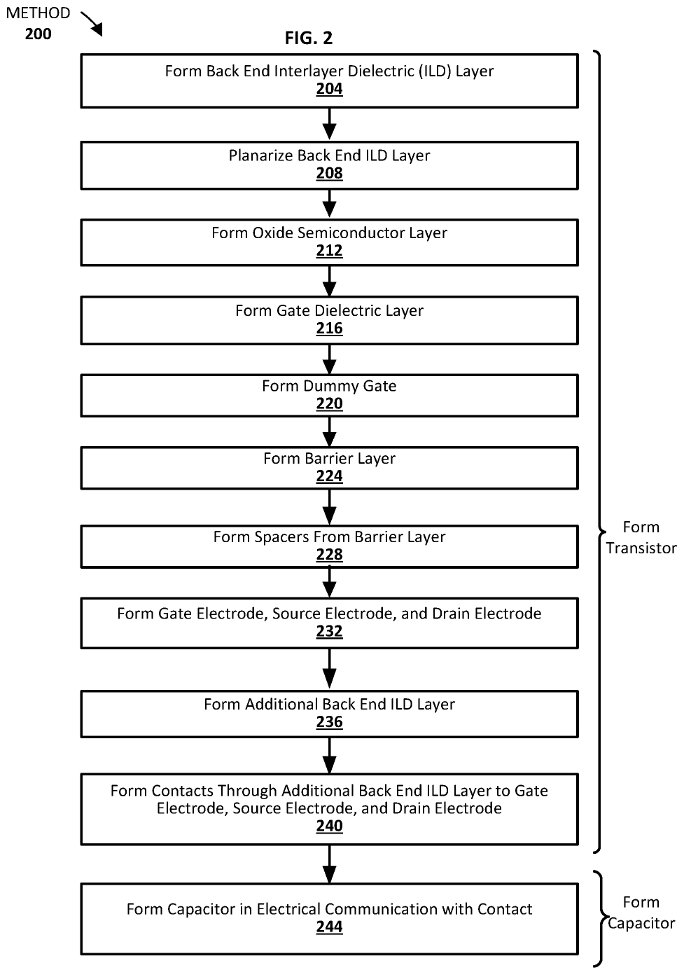

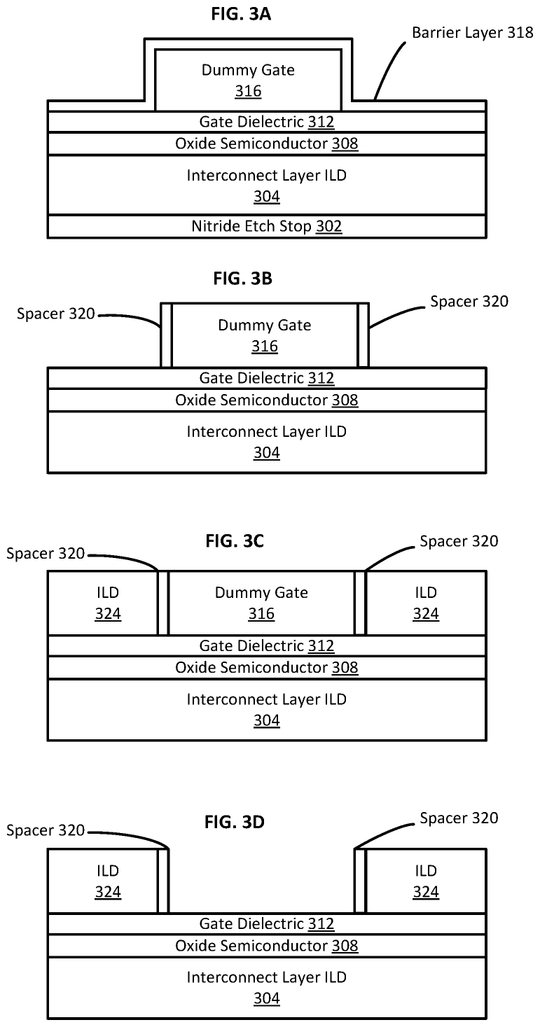

Examples of the back end memory device 170 are described below in more detail in the context of FIGS. 2 and 3A-3G.

Methodology and Architecture

FIG. 2 is a flow diagram of an example method 200 for fabricating a back end memory device within an interconnect layer, in accordance with an embodiment of the present disclosure.

The description of the method 200 is accompanied by concurrent descriptions of schematic cross-sections of corresponding example interconnect structures. These cross-sections are depicted in FIGS. 3A to 3G and are taken in a direction parallel to the gate.

As can be seen in this example case, the various processes of the method 200 can be organized for convenience of explanation into two meta-processes: (1) forming a transistor (the “1T” portion of the 1T/1C memory device); and (2) forming a capacitor (the “1C” portion of the 1T/1C memory device). The method 200 begins by forming 204 a back end interlayer dielectric (ILD) layer 304, as shown in FIG. 3A. In one example, the back end ILD layer 304 insulates an underlying device layer and/or an underlying interconnect layer, and may further include one or more interconnect features (not shown for clarity of explanation) passing through or disposed within the insulator material so as to electrically couple devices of the device layer to other interconnect structures and/or contacts. Example insulator materials that can be used for the back end ILD layer 304 include, for instance, nitrides (e.g., Si₃N₄), oxides (e.g. SiO₂, Al₂O₃), oxynitrides (e.g., SiOₓN_{y}), carbides (e.g., SiC), oxycarbides, polymers, silanes, siloxanes, or other suitable insulator materials. In some embodiments, the back end ILD layer 304 is implemented with ultra-low-k insulator materials, low-k dielectric materials, or high-k dielectric materials depending on the application. Example low-k and ultra-low-k dielectric materials include porous silicon dioxide, carbon doped oxide (CDO), organic polymers such as perfluorocyclobutane or polytetrafluoroethylene, fluorosilicate glass (FSG), and organosilicates such as silsesquioxane, siloxane, or organosilicate glass. Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Techniques for forming 204 the back end ILD layer 304 can be any of a wide range of suitable deposition techniques, including but not necessarily limited to: physical vapor deposition (PVD); chemical vapor deposition (CVD); spin coating/spin-on deposition (SOD); and/or a combination of any of the aforementioned. Other suitable configurations, materials, deposition techniques, and/or thicknesses for back end ILD layer 304 will depend on a given application and will be apparent in light of this disclosure.

In some examples, the back end ILD layer 304 is formed on an etch stop layer 302. The etch stop layer 302 is often deposited between layers within an integrated circuit to protect underlying layers from etchants and etching processes used in subsequently deposited layers. The etch stop layer 302 is typically a material that is either unaffected by etches used to etch successive ILD layers or has a slower etch rate that the feature intended to be etched (e.g., a metal feature, an ILD layer). Thus an etch stop layer protects underlying features from processing performed on features above the etch stop layer. Examples materials used for the etch stop layer 302 include alumina (Al₂O₃), zirconia (ZrO₂), silicon nitride, aluminum nitride (AlN), titanium nitride (TiN), among others. The etch stop layer 302 is omitted from FIGS. 3B-3G for clarity of explanation.

The back end ILD layer 304 is planarized 208 so that subsequent deposition and/or patterning (e.g., photolithography and etch) processes can operate on a surface that is more uniform and flatter than the as-deposited surface. Planarization and/or polishing techniques include chemical-mechanical planarization (CMP) process or other appropriate polishing/planarization process as desired.

As also shown in FIG. 3A, an oxide semiconductor layer 308 is formed 212 on the planarized back end ILD layer 304. The oxide semiconductor layer 308 forms one layer of a transistor of the 1T/1C memory cell according to an embodiment of the present disclosure. Examples of materials used for the oxide semiconductor 308 include indium gallium zinc oxide (IGZO), In₂O₃, SnO, Ga₂O₃, ZnO, ZnON, indium zinc oxide (IZO). The oxide semiconductor layer 308, which can be either amorphous or crystalline, is formed 212 by, for example, sputtering, epitaxial growth, chemical vapor deposition, metalorganic chemical vapor deposition (MOCVD), atomic layer deposition (ALD), among other deposition techniques.

As described above, the use of an oxide semiconductor layer 308 as a component of a memory cell has a number of advantages. For example, back end memory devices including the oxide semiconductor layer 308 have significantly lower leakage when the back end memory device is in an “off” state (not being read or written to) than memory devices using a more traditional material (e.g., silicon). For example, a silicon-based transistor connected to a MIM capacitor may have an off state leakage current that is on the order of 1×10⁻¹⁰ amps. A similarly configured MIM capacitor using an oxide semiconductor 308 in place of silicon for a transistor element may have an off state leakage current that is on the order of 1×10⁻¹⁴, 1×10⁻²⁰, or lower. This lower off state leakage current enables the design and fabrication of smaller capacitors compared to memory devices traditionally fabricated in the device layer for reasons presented above, among others.

Another advantage of using an oxide semiconductor layer as a component in a transistor of a 1T/1C memory cell is that ranges of deposition temperatures of the oxide semiconductor layer 308 are compatible with other back end processes (e.g., metal deposition for metal interconnects) and materials used for metal interconnects. For example, formation 212 of the oxide semiconductor layer 308 can, in some examples, take place at from 20° C. to a range of from 350° C. to 450° C., or from 400° C. to 500° C. These temperatures are, in particular, achievable when forming the oxide semiconductor layer 308 as an amorphous layer. Regardless, these formation 212 temperatures are sufficiently low that metal diffusion from metal interconnects is not activated. This in turn reduces the likelihood of electrical shorts (or other diffusion-induced defects) forming between metal interconnects.

Another advantage of using an oxide semiconductor layer 308 is that the charge carriers in many of the materials identified above (such as IGZO) are electrons, and not holes. For this reason, junction leakage is dramatically reduced or eliminated because the transistor can transmit a single type of charge carrier overwhelmingly in one current direction (corresponding to an “on” state).

Continuing with FIG. 3A, a gate dielectric layer 312 is formed 216 on the oxide semiconductor layer 308 to provide an insulating separation between the gate (shown in subsequent figures) and the oxide semiconductor layer 308. The gate dielectric layer 312 can be formed 216 using any of the materials and any of the processes already described above in the context of the interconnect layer ILD 304. In addition to those materials already described above, other examples of the gate dielectric layer 312 materials include HfO₂ and Ta₂O₃, among others.

A dummy gate 316 is formed 220 on the gate dielectric layer 312 as shown in FIG. 3A. The dummy gate 316 is formed as a temporary structure to facilitate formation of other features of a back end memory device, as described below. In examples, the dummy gate 316 can be formed by depositing amorphous silicon via chemical vapor deposition or sputtering, or in other examples by depositing amorphous germanium via chemical vapor deposition or sputtering. In other examples, the dummy gate 316 is formed by sputtering III-V semiconductor materials.

The material used to form the dummy gate 316 can be any of a variety of materials that can be selectively removed by an etch that removes the dummy gate 316 material faster than oxide and/or nitrides used elsewhere in the back end memory device.

A barrier layer 318 is then formed 224 over the dummy gate 316 and the exposed portions of the gate dielectric layer 312, as shown in FIG. 3A. The barrier layer 318 is formed 224 of Si₃N₄, any of silicon oxide nitrides (SiOxNy), and SiO₂, among materials. Deposition techniques include using any of the techniques described above in the context of formation of the interconnect ILD layer 304.

Turing now to FIG. 3B, the barrier layer 318 is etched using a directional etch to form 228 spacers 320. The spacers 320 have at least three purposes in the back end memory device described herein. First, the spacers 320 define a space within which a gate material can be formed without resorting to traditional patterning (e.g., photolithography) processing. Second, using the spacers 320 to define a space within which a gate material is formed helps reduce gate dimensional variations between back end memory devices across a substrate. This variation, which can be common when using traditional patterning techniques, can increase off state leakage for a 1T/1C device. Reducing this variation improves uniformity of dimensions of back end memory device gates across a substrate, thus improving uniformity of back end memory device performance (e.g., retention time, low off state leakage) across a substrate. Using the spacers 320, variation in a dimension between the spacers 320 (and thus a formed gate electrode 328, described below), can be as low as 200 nm, 100 nm, 50 nm, or lower.

Examples of directional etches that preferentially etch surfaces perpendicular to the direction of the etch, include, but are not limited to, dry etches such as reactive ion etches (RIE) using ozone, ionized argon, among others. The result of applying a directional etch to the barrier layer 318 is removal of portions of the barrier layer 318 except those in contact on side surfaces of the dummy gate 316, indicated as spacers 320 in FIG. 3B.

Formation 232 of a gate electrode, source electrode, and drain electrode of the back end memory device begins by formation of ILD 324 using any of the above-indicated materials, as shown in FIG. 3C. The ILD 324 is formed on a side of each of spacers 320 opposite that of the dummy gate 316. The formation and planarization of the ILD 324 and dummy gate 316 can be accomplished using any of the planarization/polishing techniques indicated above. As shown in FIG. 3D, the dummy gate 316 is removed using an etch that is selective to the dummy gate 316 material. For example, if the dummy gate 316 is formed from silicon, any of a number of etch compositions and processes can be selected to remove the dummy gate 316 while leaving the spacers 320 an ILD 324.

As mentioned above, the spacers 320 define spaces across a substrate within which uniformly dimensioned gate electrodes 328 are formed 232. This use of spacers to position a gate with low variability can be colloquially referred to as a “self-aligned” gate because some elements of traditional patterning techniques can be avoided by using the spacers 320. An example of a gate electrode 328 formed 232 between two proximate spacers 320 is shown in FIG. 3E. Examples of materials used for the gate electrode 328 may include a wide range of materials, such as polysilicon, or various suitable metals or metal alloys, such as aluminum (Al), tungsten (W), titanium (Ti), tantalum (Ta), copper (Cu), titanium nitride (TiN), or tantalum nitride (TaN), for example. These materials can be deposited by sputtering, chemical vapor deposition, pressure enhanced chemical vapor deposition, ALD, among other techniques.

The ILD 324 is removed (along with underlying portions of the gate dielectric 312 formerly in contact with or adjacent to ILD 324), as shown in FIG. 3E using an etch selective to the ILD material and/or by traditional patterning techniques. The ILD 324 is replaced with metal to form 232 a source electrode 332A and a drain electrode 332B (collectively “electrodes 332”) as shown in FIG. 3F. The electrodes 332 form a Shottky diode with the single carrier oxide semiconductor 308. Examples of metals that can be used for the electrodes 332 include, but are not limited to titanium, titanium nitride (TiN), palladium, tungsten, aluminum, cobalt, copper, molybdenum, ruthenium, tantalum nitride (TaN), and tantalum, among others.

As also shown in FIG. 3F, the source electrode 332A is shown as disposed proximate to a first portion of the oxide semiconductor 308. This first portion corresponds to the source region of the memory cell transistor. The gate dielectric 312 and the gate electrode 328 are disposed proximate to a center portion of the oxide semiconductor 308. This center portion corresponds to the channel region of the memory cell transistor. The drain electrode 332B is disposed proximate to a second portion of the oxide semiconductor 308 that is on an opposite side of the center portion from the first portion. This second portion corresponds to the drain region. These designations of the “first,” “center,” and “second” portions are for convenience of explanation. While the oxide semiconductor 308, and the corresponding source, drain, and channel regions, are generally not doped, the conductivity of some or all of source, drain, and channel regions can be altered by exposing the oxide semiconductor 308 to a plasma. A plasma treatment can modify the composition of the oxide semiconductor 308 so that a concentration of oxygen vacancies is increases. This increases a concentration of n-type carriers, which in turn increases conductivity of the plasma treated portion of the oxide semiconductor.

An additional back end ILD layer 336 is formed 236 on an exposed surface of the source electrode 332A, spacers 320, the gate electrode 328, and the drain electrode 332B using any of the above described materials and methods.

As shown in FIG. 3G, contacts 340 are then formed 240 by patterning the additional back end ILD layer 336 and forming 240 the contacts 340 (interconnects, such as vias) within a channel or cavity formed within the additional back end ILD layer 336. The contacts 340 are in contact with or otherwise electrically coupled with a corresponding one of the source electrode 332A, the gate electrode 328, and the drain electrode 332B. Example materials used for the contacts 340 include copper, aluminum, TiN, and TaN, among others. These materials can be formed 240 using CVD, PE CVD, sputtering, among others.

The contacts 340 are electrically isolated from one another by encapsulating the contacts 340 within an ILD layer 336, as described above. A capacitor 348 is then formed 244 in contact with or otherwise configured for electrical communication with one of the contact 340 (in this case, contact corresponding to the source electrode 332A) so that, upon activating the transistor of the back end memory device 350, an electrical charge can be stored, discharged, or read from the capacitor 348.

An example configuration of a back end memory device 350 fabricated according to the method 200 described above is shown in FIG. 3G.

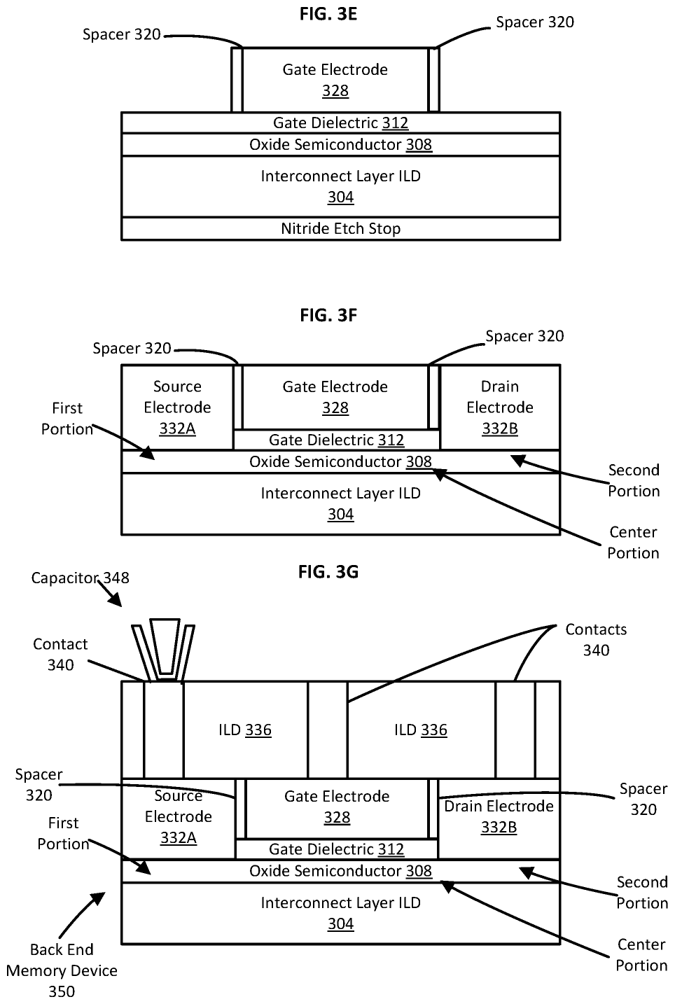

As described above, back end memory devices of the present disclosure are disposed with layers containing metal interconnects, and not within a device layer, on a substrate. To illustrate the example back end memory device 350 within this context, FIG. 4 illustrates the example back end memory device 350 disposed within a back end layer 400.

As illustrated in FIG. 4, the back end layer 400 includes interconnect layers 404, 408, and 412. While not shown, for clarity, one or more of the interconnect layers 404, 408, and 412 may include one or more interconnect features as via and/or metal lines that place various transistors and/or back end memory devices 350 in contact suitable for electrical communication.

Alternative Architecture

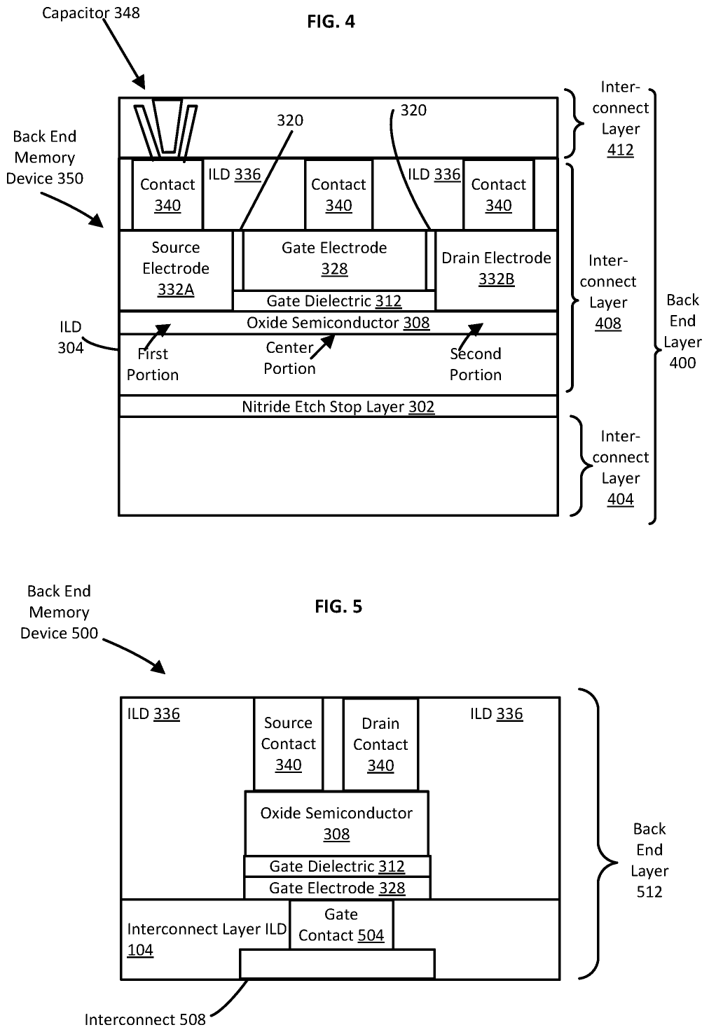

FIG. 5 illustrates an alternative configuration of a back end memory device 500. In this configuration, the order of some of the various layers of the back end memory device 500 is different than the configuration shown in FIG. 3G and FIG. 4 of the back end memory device 350. Specifically, the back end memory device 500 has a gate contact 504 that is on a side of the oxide semiconductor 308 that is opposite that of the source and drain contacts 340 (the source and drain regions are not shown in FIG. 5). An underlying interconnect 508 (e.g., a “word line”), can then be used to connect the gates of a plurality of back end memory devices 500 in a back end layer 512 together or alternatively make other types of electrical connections to the gate contact 504 within the integrated circuit. A source electrode (not shown) and a drain electrode (also not shown) are each in contact or otherwise capable of electrical communication with a corresponding contact.

The method 200 is applicable to fabrication of the back end memory device 500 shown in FIG. 5 except that the order of the various processes of the method 200 are performed in an order used to fabricate the device 500.

Analytical Techniques

Use of the techniques and structures provided herein may be detectable using tools such as: electron microscopy including scanning/transmission electron microscopy (SEM/TEM), scanning transmission electron microscopy (STEM), and reflection electron microscopy (REM); composition mapping; x-ray crystallography or diffraction (XRD); energy-dispersive x-ray spectroscopy (EDS); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, in some embodiments, such tools may indicate the presence of a back end memory device within an interconnect layer, and indicate the use of an oxide semiconductor (example compositions of which are indicated above) as an element of a transistor used as an element of a back end memory device.

### Example System

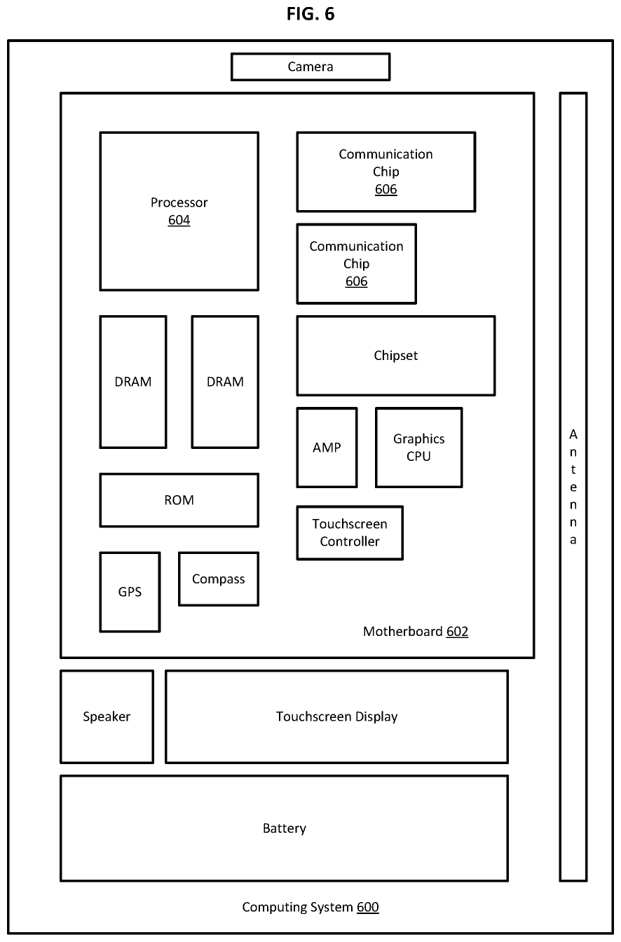

FIG. 6 is an example computing system implemented with one or more of the integrated circuit structures as disclosed herein, in accordance with some embodiments of the present disclosure. As can be seen, the computing system 600 houses a motherboard 602. The motherboard 602 may include a number of components, including, but not limited to, a processor 604 and at least one communication chip 606, each of which can be physically and electrically coupled to the motherboard 602, or otherwise integrated therein. As will be appreciated, the motherboard 602 may be, for example, any printed circuit board, whether a main board, a daughterboard mounted on a main board, or the only board of system 600, etc.

Depending on its applications, computing system 600 may include one or more other components that may or may not be physically and electrically coupled to the motherboard 602. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 600 may include one or more integrated circuit structures or devices configured in accordance with an example embodiment (e.g., to include one or more back end memory devices disposed in one or more interconnect layers of an integrated circuit, as various described herein). In some embodiments, multiple functions can be integrated into one or more chips (e.g., for instance, note that the communication chip 606 can be part of or otherwise integrated into the processor 604).

The communication chip 606 enables wireless communications for the transfer of data to and from the computing system 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others. In some embodiments, communication chip 606 may include one or more transistor structures having a gate stack an access region polarization layer as variously described herein.

The processor 604 of the computing system 600 includes an integrated circuit die packaged within the processor 604. In some embodiments, the integrated circuit die of the processor includes onboard circuitry that is implemented with one or more integrated circuit structures or devices as variously described herein. The term “processor” may refer to any device or portion of a device that processes, for instance, electronic data from registers and/or memory to transform that electronic data into other electronic data that may be stored in registers and/or memory.

The communication chip 606 also may include an integrated circuit die packaged within the communication chip 606. In accordance with some such example embodiments, the integrated circuit die of the communication chip includes one or more integrated circuit structures or devices as variously described herein. As will be appreciated in light of this disclosure, note that multi-standard wireless capability may be integrated directly into the processor 604 (e.g., where functionality of any chips 606 is integrated into processor 604, rather than having separate communication chips). Further note that processor 604 may be a chip set having such wireless capability. In short, any number of processor 604 and/or communication chips 606 can be used. Likewise, any one chip or chip set can have multiple functions integrated therein.

In various implementations, the computing system 600 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

### Further Example Embodiments

The following examples pertain to further embodiments, from which numerous permutations and configurations will be apparent.

Example 1 includes an integrated circuit device comprising: a substrate comprising a semiconductor material; a device layer disposed on the substrate comprising a plurality of transistors; a plurality of interconnect layers over the device layer, at least some of the interconnect layers comprising a plurality of metal features and insulation between the metal features; and a back end memory device within at least one layer of the plurality of interconnect layers, the back end memory device including an oxide semiconductor layer over at least a portion of the insulation of an interconnect layer, a gate electrode, and a gate dielectric layer between the oxide semiconductor layer and the gate electrode.

Example 2 includes the subject matter of Example 1, further comprising peripheral memory device circuitry disposed under the back end memory device within a device layer of the substrate.

Example 3 includes the subject matter of either of Examples 1 or 2, wherein the oxide semiconductor layer includes a first portion, a second portion opposite the first portion, and a center portion between the first portion and the second portion.

Example 4 includes the subject matter of Example 3, further comprising a source electrode on the first portion of the oxide semiconductor layer and a drain electrode on the second portion of the oxide semiconductor layer, wherein the first portion of the oxide semiconductor layer corresponds to a source region of a memory cell transistor, the center portion of the oxide semiconductor layer corresponds to a channel region of the memory cell transistor, and the second portion of the oxide semiconductor layer corresponds to a drain region of the memory cell transistor.

Example 5 includes the subject matter of Example 4, further comprising a first electrical contact in contact with the source electrode, a second electrical contact in contact with the gate electrode, and a third electrical contact in contact with the drain electrode.

Example 6 includes the subject matter of Example 5, wherein the gate electrode and the second electrical contact are on a side of the oxide semiconductor layer opposite from the first electrical contact and the second electrical contact.

Example 7 includes the subject matter of any of Examples 1 through 6, wherein the oxide semiconductor layer is a layer of indium gallium zinc oxide, or otherwise includes indium, gallium, zinc, and oxygen.

Example 8 includes the subject matter of Example 7, wherein the indium gallium zinc oxide is amorphous.

Example 9 includes the subject matter of any of Examples 1 through 6, wherein the oxide semiconductor layer is a layer of indium zinc oxide, or otherwise includes indium, zinc, and oxygen.

Example 10 includes the subject matter of any of Examples 1 through 6, wherein the oxide semiconductor layer is a layer of indium oxide or otherwise includes indium and oxygen.

Example 11 includes the subject matter of any of Examples 1 through 6, wherein the oxide semiconductor layer is a layer of tin oxide or otherwise includes tin and oxygen.

Example 12 includes the subject matter of any of Examples 1 through 6, wherein the oxide semiconductor layer is a layer of zinc oxide or otherwise includes zinc and oxygen.

Example 13 includes the subject matter of any of Examples 1 through 6, wherein the oxide semiconductor layer is a layer of gallium oxide or otherwise includes gallium and oxygen.

Example 14 includes the subject matter of any of Examples 1 through 6, wherein the oxide semiconductor layer is a layer of zinc oxide nitride or otherwise includes zinc, oxygen, and nitrogen.

Example 15 includes the subject matter of any of Examples 1 through 14, further comprising a first insulating spacer disposed between a source electrode and the gate electrode; and second insulating spacer disposed between a drain electrode and the gate electrode.

Example 16 includes the subject matter of any of Examples 1 through 15, further comprising a capacitor in contact with the integrated circuit device.

Example 17 includes a computing system that includes the subject matter of any of Examples 1 through 16.

Example 18 includes an integrated circuit memory device comprising: an oxide semiconductor layer disposed within an interconnect layer of an integrated circuit, the oxide semiconductor layer having a first portion, a second portion opposite the first portion, and a center portion between the first portion and the second portion, the first portion corresponding to a source region of a memory cell transistor, the center portion corresponding to a channel region of the memory cell transistor, and the second portion corresponding to a drain region of the memory cell transistor; a gate electrode over the channel region of the oxide semiconductor layer; and a gate dielectric layer between the oxide semiconductor and the gate electrode.

Example 19 includes the subject matter of Example 18, further comprising an electrical contact in contact with the gate electrode on a first side of the gate dielectric layer, and at least one electrical contact in contact with the oxide semiconductor on a second side of the gate dielectric opposite the first side.

Example 20 includes the subject matter of Example 19, further comprising a source electrode on the source region of the oxide semiconductor layer and a drain electrode on the drain region of the oxide semiconductor layer.

Example 21 includes the subject matter of Example 20, further comprising a first electrical contact in contact with the source electrode, a second electrical contact in contact with the gate electrode, and a third electrical contact in contact with the drain electrode.

Example 22 includes the subject matter of any of Examples 18 through 21, wherein the oxide semiconductor layer is a layer of indium gallium zinc oxide or otherwise includes indium, gallium, zinc, and oxygen.

Example 23 includes the subject matter of Example 22, wherein the indium gallium zinc oxide is amorphous.

Example 24 includes the subject matter of any of Examples 18 through 21, wherein the oxide semiconductor layer is a layer of indium zinc oxide or otherwise includes indium, zinc, and oxygen.

Example 25 includes the subject matter of any of Examples 18 through 21, wherein the oxide semiconductor layer is a layer of indium oxide or otherwise includes indium and oxygen.

Example 26 includes the subject matter of any of Examples 18 through 21, wherein the oxide semiconductor layer is a layer of tin oxide or otherwise includes tin and oxygen.

Example 27 includes the subject matter of any of Examples 18 through 21, wherein the oxide semiconductor layer is a layer of zinc oxide or otherwise includes zinc and oxygen.

Example 28 includes the subject matter of any of Examples 18 through 21, wherein the oxide semiconductor layer is a layer of gallium oxide or otherwise includes gallium and oxygen.

Example 29 includes the subject matter of any of Examples 18 through 21, wherein the oxide semiconductor layer is a layer of zinc oxide nitride or otherwise includes zinc, nitrogen, and oxygen.

Example 30 includes the subject matter of any of Examples 18 through 29, further comprising a first insulating spacer disposed between a source electrode and the gate electrode; and a second insulating spacer disposed between a drain electrode and the gate electrode.

Example 31 includes a capacitor that further includes the subject matter of any of Examples 18 through 30, Example 32 includes a computing system comprising the subject matter of any of

Examples 18 through 31,

Example 33 includes method for forming a back end memory device comprising: forming a back end interlayer dielectric layer over a substrate; forming an oxide semiconductor layer on the back end interlayer dielectric layer, the oxide semiconductor layer including a channel region between a source region and a drain region; forming a gate dielectric layer on the oxide semiconductor layer over the channel region; forming a gate electrode over the gate dielectric; forming a source electrode over the source region; forming a drain electrode over the drain region; and forming a capacitor in the back end interlayer dielectric layer, the capacitor having at least one electrode in contact with one of the source, drain, or gate electrodes.

Example 34 includes the subject matter of Example 33, further comprising forming a dummy gate prior to forming the gate electrode.

Example 35 includes the subject matter of Example 34, forming insulating spacers on opposing sides of the dummy gate; removing the dummy gate, the insulating spacers thus defining a space therebetween; and forming the gate electrode within the space defined by the insulating spacers.

1. An integrated circuit device comprising:
a device layer comprising a plurality of transistors;
a plurality of interconnect layers over the device layer, at least some of the interconnect layers comprising a plurality of metal features and insulation between the metal features; and
a back end memory device within at least one layer of the plurality of interconnect layers, the back end memory device including
an oxide semiconductor layer over at least a portion of the insulation of an interconnect layer,
a gate electrode, and
a gate dielectric layer between the oxide semiconductor layer and the gate electrode.

2. The integrated circuit device of claim 1, further comprising peripheral memory device circuitry within the device layer.

3. The integrated circuit device of claim 1, wherein the oxide semiconductor layer includes a first portion, a second portion, and a center portion between the first portion and the second portion, the integrated circuit device further comprising:
a source electrode on the first portion of the oxide semiconductor layer; and
a drain electrode on the second portion of the oxide semiconductor layer;
wherein the first portion of the oxide semiconductor layer corresponds to a source region of a memory cell transistor, the second portion of the oxide semiconductor layer corresponds to a drain region of the memory cell transistor, and the gate dielectric layer is between the gate electrode and the center portion of the oxide semiconductor layer.

4. (canceled)

5. The integrated circuit device of claim 3, further comprising a first electrical contact in contact with the source electrode, a second electrical contact in contact with the gate electrode, and a third electrical contact in contact with the drain electrode.

6. The integrated circuit device of claim 5, wherein the gate electrode and the second electrical contact are on a side of the oxide semiconductor layer opposite from the first electrical contact and the second electrical contact.

7. The integrated circuit device of claim 1, wherein the oxide semiconductor layer includes indium, gallium, zinc, and oxygen.

8. The integrated circuit device of claim 7, wherein the oxide semiconductor layer is amorphous.

9. The integrated circuit device of claim 1, wherein the oxide semiconductor layer is a layer of one or more of indium zinc oxide, indium oxide, tin oxide, zinc oxide, gallium oxide, and zinc oxide nitride.

10. The integrated circuit device of claim 1, further comprising:
a first insulating spacer between a source electrode and the gate electrode; and
a second insulating spacer between a drain electrode and the gate electrode.

11. The integrated circuit device of claim 1, further comprising a capacitor in contact with the integrated circuit device.

12. A computing system comprising the integrated circuit device of claim 1.

13. An integrated circuit memory device comprising:
an oxide semiconductor layer within an interconnect layer, the oxide semiconductor layer having a first portion, a second portion, and a center portion between the first portion and the second portion, the first portion corresponding to a source region of a memory cell transistor, and the second portion corresponding to a drain region of the memory cell transistor;
a gate electrode over the oxide semiconductor layer; and
a gate dielectric layer between the center portion of the oxide semiconductor and the gate electrode.

14. The integrated circuit memory device of claim 13, further comprising an electrical contact in contact with the gate electrode on a first side of the gate dielectric layer, and at least one electrical contact in contact with the oxide semiconductor on a second side of the gate dielectric opposite the first side.

15. The integrated circuit memory device of claim 13, further comprising a source electrode on the source region of the oxide semiconductor layer and a drain electrode on the drain region of the oxide semiconductor layer.

16. The integrated circuit memory device of claim 15, further comprising a first electrical contact in contact with the source electrode, a second electrical contact in contact with the gate electrode, and a third electrical contact in contact with the drain electrode.

17. The integrated circuit memory device of claim 13, wherein the oxide semiconductor layer is a layer of indium gallium zinc oxide.

18. The integrated circuit memory device of claim 17, wherein the indium gallium zinc oxide is amorphous.

19. The integrated circuit memory device of claim 13, wherein the oxide semiconductor layer is a layer of one or more of indium oxide, tin oxide, zinc oxide, gallium oxide, zinc oxide nitride, indium zinc oxide.

20. The integrated circuit memory device of claim 13, further comprising:
a first insulating spacer between a source electrode and the gate electrode; and
a second insulating spacer between a drain electrode and the gate electrode.

21. The integrated circuit memory device of claim 13, further comprising a capacitor.

22-25. (canceled)
